(19) United States
(12) Patent Application Publication
(10) Pub. No.: US 2006/0081864 A1
(43) Pub. Date: Apr. 20, 2006

(54) Encapsulating composition for LED

(75) Inventor: Keiichi Nakazawa, Tsukuba (JP)

Correspondence Address: BROOKS KUSHMAN P.C., 1000 TOWN CENTER, TWENTY-SECOND FLOOR, SOUTHFIELD, MI, 48075, US

(73) Assignee: Wacker-Chemie GmbH, Munich (DE)

(21) Appl. No.: 11/291,175

(22) Filed: Dec. 2, 2005

Related U.S. Application Data
(63) Continuation of application No. PCT/EP04/06009, filed on Jun. 3, 2004.

(30) Foreign Application Priority Data
Jun. 3, 2003 (JP) 2003-158040

(51) Int. Cl. H01L 33/00

(52) U.S. Cl. 257/98

(57) ABSTRACT

An organopolysiloxane composition which cures to a resinous solid has high strength, transparency, and resistance to thermal- and photo-degradation, and is especially suited for encapsulating LEDs. The composition contains specific addition curable organopolysiloxanes having D, T, and Q units, and a proportion of silicon-bonded aromatic groups.

### CROSS-REFERENCE TO RELATED APPLICATIONS

This application is a continuation of PCT application Serial No. PCT/EP2004/006009, filed Jun. 3, 2004, to which priority is claimed, and which claims the benefit of Japanese Application No. JP 2003-158040, filed Jun. 3, 2003, to which priority is also claimed.

### BACKGROUND OF THE INVENTION

1. Field of the Invention

The present invention relates to a polyorganosiloxane composition for encapsulating light emitting diodes (hereafter abbreviated as LED), and more particularly to a polyorganosiloxane composition that becomes resin-like on curing and is ideal for encapsulating both LEDs that emit light in the blue through ultraviolet spectrum, and white light emitting elements.

2. Description of the Related Art

LEDs have a variety of favorable properties including long life, high brightness, low voltage, small size, an almost complete absence of heat rays, an ability to freely modulate light emission with high switching speeds, good retention of light emitting efficiency even at low temperatures, and suitability for incorporation into waterproof structures. Consequently the potential uses for LEDs continue to expand.

Of the various applications for LEDs, the development of LEDs that emit light in the blue through ultraviolet spectrum has been one reason for the growing number of applications for LEDs. One example of an application for these types of LEDs is as the white light emitting elements used in lighting sources, display devices, and the back lights in liquid crystal displays. These white light emitting devices include devices in which a GaN (gallium nitride) based LED, which emits light in the blue through ultraviolet spectrum is combined with a fluorescent material, and devices in which three LEDs of red, blue, and yellow are combined together.

In an LED, a compound semiconductor chip and electrodes are encapsulated inside a protective transparent resin. In the case of a light emitting element that employs a combination with a fluorescent material, by dispersing the fluorescent material within the resin used to encapsulate the LED for example, light in a range from blue (490 nm) to a shorter wavelength (365 nm) emitted by the LED is incident on the fluorescent material. Depending on the selection of the fluorescent material, this light is then scattered at a variety of wavelengths, thus generating a white light emitting element.

Conventionally, epoxy resins have typically been used for encapsulating LEDs. Japanese Patent Laid-Open JP95099345A discloses an example of a white light emitting element employing a combination of a blue through ultraviolet LED chip and a fluorescent material, in which the LED structure is encapsulated with an epoxy resin. However, although epoxy resins offer excellent transparency, they are not entirely satisfactory in terms of their heat resistance and light resistance relative to higher brightness and shorter wavelength LEDs. In other words, when ultraviolet light or the like is irradiated onto an epoxy based resin encapsulated body, linkages within the organic polymer are broken, causing a deterioration in a variety of the optical and chemical characteristics of the resin. As a result, the resin in the region surrounding the light emitting diode chip gradually yellows, which affects the light coloring and ultimately restricts the lifespan of the light emitting device. Even in the case of blue light LEDs which contain no fluorescent materials, epoxy resins are still not entirely satisfactory in terms of their light resistance and heat resistance.

On the other hand, silicone based polymer compounds have long been proposed as suitable resins for encapsulating LEDs, as they offer excellent transparency as well as favorable light resistance. For example, Japanese Patent Laid-Open JP79019660A discloses a resin encapsulation comprising an internal layer of a silicone resin and an external layer of an epoxy resin, wherein the silicone resin used is a resin with rubber-like elasticity, also known as an elastomer. Furthermore, Japanese Patent Laid-Open JP94314816A discloses the use of a siloxane compound as a resin for encapsulating LEDs, wherein the siloxane compound comprises alkoxy groups that undergo reaction with the hydroxyl groups on the surface of the compound semiconductor, thereby generating a silicone resin through a condensation reaction. Accordingly, in this case, a polymer compound with an organosiloxane unit is used as the encapsulant.

Japanese Patent Laid-Open JP2002314142A discloses the use of silicone for encapsulating a light emitting element comprising a combination of an ultraviolet LED and a fluorescent material. A liquid silicone containing fluorescent material dispersed therein is used for the encapsulation, and when silicones which formed a gel-like product on curing were compared with those that formed a rubber-like product, it was found that the rubber-like products provided better protection of the LED.

The silicones with organosiloxane units reported in the above conventional techniques display excellent transparency and provide sufficient elasticity to enable the absorption of impacts, but are also prone to deformation, which can sometimes cause breakage of the LED bonding wire, and do not offer an entirely satisfactory level of mechanical strength. Accordingly, improvements in this balance between strength and hardness have been keenly sought.

### SUMMARY OF THE INVENTION

The object of the present invention is directed to solving the problems of the prior technology. These and other objects are solved by providing silicone encapsulating materials for LEDs, especially for LEDs emitting blue to ultraviolet light spectrum, which offer excellent transparency, light and heat resistance, which are hard and resistant to cracking, which display little shrinkage during molding, and which provide an excellent balance between strength and hardness.

Based on intensive research, it has now been surprisingly discovered that by employing an LED encapsulating composition comprising a specific polyorganosiloxane that undergoes an addition reaction and on curing forms a resin, in the presence of an addition reaction catalyst, an LED encapsulating composition could be prepared which displays a high transmittance and high refractive index, as well as excellent light resistance and heat resistance, is hard and resistant to cracking, and displays little shrinkage during molding.

### DETAILED DESCRIPTION OF THE PREFERRED EMBODIMENTS(S)

A first aspect of the present invention provides an LED encapsulating composition, which becomes resinous material by curing, comprising (a) a polyorganosiloxane component, which comprises at least one polyorganosiloxane and has an average composition formula, as a mixture of said polyorganosiloxane, represented by (R¹R²R³SiO_{1/2})_{M}.(R⁴R⁵SiO_{2/2})_{D}.(R⁶SiO_{3/2})_{T}. (SiO_{4/2})_{Q} (wherein, R¹ to R⁶ are identical or different radicals selected from the group consisting of an organic group, a hydroxyl group, and a hydrogen atom, and at least one of R¹ to R⁶ is either a hydrocarbon group with a multiple bond, and/or a hydrogen atom, M, D, T, and Q each represent a number within a range from 0 to less than 1, M+D+T+Q=1, and Q+T>0), and (b) an addition reaction catalyst in an effective quantity, wherein at least one of R¹ to R⁶ represents identical or different aromatic groups.

LED encapsulating composition according to the first aspect, wherein 3.0>(2D+3T+4Q)/(D+T+Q)>2.0 is satisfied.

A third aspect of the present invention provides the LED encapsulating composition according to any one of the first and second aspects, wherein silicon atoms bonded directly to hydrogen atoms in the polyorganosiloxane account for no more than 40 mol % of the total number of silicon atoms.

A fourth aspect of the present invention provides the LED encapsulating composition according to any one of the first through third aspects, wherein the component (a) comprises (a-1) at least one polyorganosiloxane, with an average composition formula of
(RⁱR²R³SiO_{1/2})_{M1}.(R⁴R⁵SiO_{2/2})_{D1}.(R⁶SiO_{3/2})_{T1}.(SiO_{4/2})_{Q1,}
which contains no hydrogen atoms bonded directly to silicon atoms, and in which at least one of R¹ to R⁶ represents a hydrocarbon group with a multiple bond (wherein, M1, D1, T1 and Q1 each represent a number within a range from 0 to less than 1, M1+D1+T1+Q1=1, and Q1+T1>0), and (a-2) at least one polyorganosiloxane, with an average composition formula of
(R¹R²R³SiO_{1/2})_{M2}.(R⁴R⁵SiO_{2/2})_{D2}.(R⁶SiO_{3/2})_{T2}.(SiO_{4/2})_{Q2},
which contains no hydrocarbon groups with a multiple bond, and in which at least one of R¹ to R⁶ represents a hydrogen atom bonded directly to a silicon atom (wherein, M2, D2, T2 and Q2 each represent a number within a range from 0 to less than 1, and M2+D2+T2+Q2=1).

A fifth aspect of the present invention provides the LED encapsulating composition according to any one of the first through third aspects, wherein the component (a) comprises (a−1) at least one polyorganosiloxane, with an average composition formula of
(R¹R²R³SiO_{1/2})_{M1}. (R⁴R⁵SiO_{2/2})_{D1}.(R⁶SiO_{3/2})_{T1}.(SiO_{4/2})_{Q1},
which contains no hydrogen atoms bonded directly to silicon atoms, and in which at least one of R¹ to R⁶ represents a hydrocarbon group with a multiple bond (wherein, M1, D1, T1 and Q1 each represent a number within a range from 0 to less than 1, M1+D1+T1+Q1=1, and Q1+T1>0), and (a-3) at least one polyorganosiloxane, with an average composition formula of
(R¹R²R³SiO_{1/2})_{M3}.(R⁴R⁵SiO_{2/2})_{D3}.(R⁶SiO_{3/2}) _{T3}.(SiO_{4/2})_{Q}3,
in which at least one of R¹ to R⁶ represents a hydrocarbon group with a multiple bond, and at least one of R¹ to R⁶ represents a hydrogen atom bonded directly to a silicon atom (wherein, M3, D3, T3 and Q3 each represent a number within a range from 0 to less than 1, and M3+D3+T3+Q3=1).

A sixth aspect of the present invention provides the LED encapsulating composition according to either one of the fourth and fifth aspects, wherein the hydrocarbon group with a multiple bond is a vinyl group.

A seventh aspect of the present invention provides an LED encapsulated with a composition according to any one of the first through sixth aspects.

Hereinafter, the present invention will be described in detail.

In the polyorganosiloxane of the component (a) in the present invention, which comprises at least one polyorganosiloxane and has an average composition formula, as a mixture of said polyorganosiloxane, represented by
(R¹R²R³SiO_{1/2})_{M}.(R⁴R⁵SiO_{2/2})_{D}.(R⁶SiO_{3/2})_{T}.(SiO_{4/2})_{Q},

R¹ to R⁶ are identical or different, and each represents a group selected from the group consisting of an organic group, a hydroxyl group, and a hydrogen atom, and at least one of R¹ to R⁶ is either a hydrocarbon group with a multiple bond that is bonded directly to a silicon atom, and/or a hydrogen atom bonded directly to a silicon atom. Furthermore, M, D, T and Q each represent a number within a range from 0 to less than 1, M+D+T+Q=1, and Q+T>0.

In the present invention, the polyorganosiloxane of the component (a) is a polymer obtained by subjecting an organosilane and/or an organosiloxane to a hydrolysis reaction or the like, wherein the average composition of the product mixture comprises branched structures of T units (R⁶SiO_{3/2}) and Q units (SiO_{4/2}), which on cross linking or the like can adopt a higher level three dimensional network structure. Accordingly, in all of the average composition formulas, Q+T>0. This type of polyorganosiloxane is also known as a silicone resin, and may be either a solid or a liquid, although liquids are preferred in the present invention due to their ease of molding when used as an LED encapsulant.

Each of R¹ to R⁶ represents either a single group or a plurality of different groups, and can be selected from the groups listed below. The formulas refer to average composition formulas, so that when selecting the groups within the structural unit (R⁴R⁵SiO_{2/2})_{D} for example, the R⁴ group may simultaneously represent more than one different group. Namely, R⁴ may simultaneously represent a methyl group, a phenyl group, and a hydrogen atom. Furthermore, the structures for linking each of the units together may differ from each of the unit structures.

Examples of R¹ to R⁶ include straight chain or branched chain alkyl or alkenyl groups of 1 to 20 carbon atoms or halogen substituted variations thereof, cycloalkyl or cycloalkenyl groups of 5 to 25 carbon atoms or halogen substituted variations thereof, aralkyl or aryl groups of 6 to 25 carbon atoms or halogen substituted variations thereof, a hydrogen atom, a hydroxyl group, alkoxy groups, acyloxy groups, ketoximate groups, alkenyloxy groups, acid anhydride groups, carbonyl groups, sugars, cyano groups, oxazoline groups, isocyanate groups, and hydrocarbon substituted versions of the above hydrocarbons.

In the present invention, at least one of R¹ to R⁶ is either a hydrocarbon group with a multiple bond that is bonded directly to a silicon atom, and/or a hydrogen atom bonded directly to a silicon atom. However, in the case of a hydrogen atom, not all of the R¹ to R⁶ substituents are so substituted, and preferably only one or two of the units are selected and substituted with hydrogen atoms. The most preferred position for a hydrogen atom in the present invention is within the (R⁴R⁵SiO_{2/2})_{D} structural unit. The multiple bond described above refers to a multiple bond that is capable of undergoing an addition reaction with a hydrogen atom bonded directly to a silicon atom, either in the presence of a catalyst or even without a catalyst, and preferred multiple bond structures include carbon-carbon double bonds and carbon-carbon triple bonds. The most preferred structure is a carbon-carbon double bond, and the most preferred hydrocarbon group with a multiple bond is a vinyl group. The most preferred position for this multiple bond is within the (R⁴R⁵SiO_{2/2})_{D} structural unit.

Examples of preferred groups for R¹ to R⁶ include straight chain or branched chain alkyl groups such as methyl, ethyl, propyl, isopropyl, n-butyl, isobutyl, tert-butyl, pentyl, isopentyl, neopentyl, hexyl, isohexyl, heptyl, isoheptyl, octyl, isooctyl, nonyl, and decyl groups; alkenyl groups such as vinyl, allyl, and hexenyl groups; an ethynyl group; cycloalkyl groups such as cyclopentyl, cyclohexyl, cycloheptyl, cyclooctyl, dicyclopentyl, and decahydronaphthyl groups; cycloalkenyl groups such as (1-, 2- and 3-)cyclopentenyl groups and (1-, 2- and 3-)cyclohexenyl groups; aralkyl and aryl groups such as phenyl, naphthyl, tetrahydronaphthyl, tolyl, and ethylphenyl groups; as well as hydrogen atoms, hydroxyl, methoxy, ethoxy, propoxy, isopropoxy, butoxy, isobutoxy, tert-butoxy, hexyloxy, isohexyloxy, 2-hexyloxy, octyloxy, isooctyloxy, 2-octyloxy, acetoxy, dimethylketoxime, methylethylketoxime, glycidyl, ethylene glycoxy, diethylene glycoxy, polyethylene glycoxy, propylene glycoxy, dipropylene glycoxy, polypropylene glycoxy, methoxyethylene glycoxy, ethoxyethylene glycoxy, methoxydiethylene glycoxy, ethoxydiethylene glycoxy, methoxypropylene glycoxy, methoxydipropylene glycoxy, and ethoxydipropylene glycoxy groups.

Of the above groups, methyl, ethyl, propyl, phenyl, and vinyl groups and a hydrogen atom are particularly preferred.

The polyorganosiloxane of the component (a) of the present invention preferably contains an aromatic group, and examples of the aromatic group include the aralkyl and aryl groups listed above, although phenyl groups are the most preferred. The quantity of aromatic groups added is preferably within a range from 5 to 90 mol %, and even more preferably from 10 to 60 mol % of all the units. If the quantity of aromatic groups is too low, then the desired improvements in heat resistance and light resistance cannot be achieved, whereas if the quantity is too high, the product becomes economically unviable. The aromatic groups may be introduced into any of the units except the (SiO_{4/2})_{Q} unit, although introduction into the (R⁴R⁵SiO_{2/2})_{D} and (R⁶SiO_{3/2})_{T} units is preferred, with the (R⁶SiO_{3/2})_{T} units being the most desirable.

Furthermore, in the component (a) of the present invention, the quantity of silicon atoms bonded directly to hydrogen atoms is preferably within a range from 1 to 40 mol %, and even more preferably from 3 to 30 mol %, and most preferably from 5 to 20 mol %, of the total quantity of silicon atoms. If this quantity is too high, then although the hardness increases, the product tends to become more brittle, whereas if the quantity is too low, then the hardness does not increase adequately. Accordingly, a quantity within the above range is desirable. Furthermore, in those cases where the component (a) comprises both a hydrocarbon group with a multiple bond and hydrogen atoms bonded directly to silicon atoms, then the quantity of silicon atoms bonded directly to hydrogen atoms is preferably within a range from 1 to 40 mol %, and even more preferably from 3 to 30 mol %, and most preferably from 5 to 20 mol %, of the total quantity of silicon atoms. At quantities exceeding 40 mol %, although the hardness of the cured product increases, it tends to become more brittle, whereas at quantities less than 1 mol %, a cured product of satisfactory hardness cannot be obtained.

M, D, T, and Q are numbers representing the relative proportions of each of the units, and each falls within a range from 0 to less than 1. Preferred ranges are from 0 to 0.6 for M, from 0.1 to 0.8 for D, from 0.1 to 0.7 for T, and from 0 to 0.3 for Q, and ideally M is from 0.1 to 0.4, D is from 0.1 to 0.6, T is from 0.3 to 0.6, and Q is 0. The value of T+Q is preferably within a range from 0.3 to 0.9, and even more preferably from 0.5 to 0.8.

The value of (2D+3T+4Q)/(D+T+Q), wherein 2D is double D, 3T is triple T and 4Q is fourfold Q, which represents the degree of branching, preferably satisfies the requirement 3.0>(2D+3T+4Q)/(D+T+Q)>2.0, and even more preferably the requirement 2.8>(2D+3T+4Q)/(D+T+Q)>2.2, and most preferably the requirement 2.8>(2D+3T+4Q)/(D+T+Q)>2.5.

In the present invention, at least one component (a) is combined with an addition reaction catalyst of the component (b) as the LED encapsulating composition. A variety of different configurations are possible including combinations of a plurality of different components (a). One example of a preferred combination comprises (a-1) at least one polyorganosiloxane, with an average composition formula of
(R¹R²R³SiO_{1/2})_{M1}.(R⁴R⁵SiO_{2/2})_{D1}.(R⁶SiO_{3/2})_{T1}. (SiO_{4/2})_{Q1},
which contains no hydrogen atoms bonded directly to silicon atoms, and in which at least one of R¹ to R⁶ represents a hydrocarbon group with a multiple bond, and (a-2) at least one polyorganosiloxane, with an average composition formula of (R¹R²R³SiO_{1/2})_{M2}.(R⁴R⁵SiO_{2/2})_{D2}.(R⁶SiO_{3/2})_{T2}.(SiO_{4/2})_{Q2}, which contains no hydrocarbon groups with a multiple bond, and in which at least one of R¹ to R⁶ represents a hydrogen atom bonded directly to a silicon atom, and this combination is ideal in terms of storage of the LED encapsulating composition itself, and the stability of the product. In the above example, the three components (a-1), (a-2), and (b) may be simply mixed together to produce the final composition, or alternatively, a combination of the component (b) and the component (a-1) may be stored, and the final composition then produced by adding the component (a-2) immediately prior to feeding and curing in a mold.

In the average composition formula of the component (a-1), M1, D1, T1, and Q1 each represent a number within a range from 0 to less than 1, M1+D1+T1+Q1=1, and Q1+T1>0. Similarly in the average composition formula of the component (a-2), M2, D2, T2, and Q2 each represent a number within a range from 0 to less than 1, and M2+D2+T2+Q2=1. In this case, preferred values for M1, D1, T1, Q1, M2, D2, T2, and Q2 are selected so that the average values for each of the M, D, T, and Q units within the mixture of the component (a-1) and the component (a-2) fall within the preferred ranges for M, D, T, and Q described above for the component (a). For example, the weight average of M1 and M2 is preferably within a range from 0 to 0.6, and even more preferably from 0.1 to 0.4.

Another example of a preferred combination of the present invention comprises the same polyorganosiloxane as the component (a-1) described above, and (a-3) at least one polyorganosiloxane, with an average composition formula of (R¹R²R³SiO_{1/2})_{M3}.(R⁴R⁵SiO_{2/2})_{D3}.(R⁶SiO_{3/2}) _{T3}.(SiO_{4/2})_{Q3} (wherein, M3, D3, T3, and Q3 each represent a number within a range from 0 to less than 1, and M3+D3+T3+Q3=1), in which at least one of R¹ to R⁶ represents a hydrocarbon group with a multiple bond, and at least one of R¹ to R⁶ represents a hydrogen atom bonded directly to a silicon atom, and this combination is ideal in terms of the properties of the cured LED encapsulating composition.

In this case, the preferred ranges for each of the structural units M, D, T, and Q are such that the average values across all of the polyorganosiloxanes are from 0 to 0.6 for M, from 0.1 to 0.8 for D, from 0.1 to 0.7 for T, and from 0 to 0.3 for Q. Ideally, M is from 0.1 to 0.4, D is from 0.2 to 0.5, T is from 0.3 to 0.6, and Q is 0.

The value of (2D+3T+4Q)/(D+T+Q), which represents the degree of branching and is calculated using the average value for each unit across all of the polyorganosiloxanes in the combined mixture, preferably satisfies the requirement 3.0>(2D+3T+4Q)/(D+T+Q)>2.0, and even more preferably the requirement 2.8>(2D+3T+4Q)/(D+T+Q)>2.2, and most preferably the requirement 2.8>(2D+3T+4Q)/(D+T+Q)>2.3.

The addition reaction catalyst of the component (b) of the present invention is a catalyst for promoting the addition reaction between a silicon atom with a bonded hydrogen atom, and a hydrocarbon group with a multiple bond, and is a widely used material. Examples of suitable metal or metal compound catalysts include platinum, rhodium, palladium, ruthenium, and iridium, and of these, platinum is preferred. In some cases the metal may be supported on fine particles of a carrier material (such as activated carbon, aluminum oxide, or silicon oxide). The addition reaction catalyst preferably employs either platinum or a platinum compound. Examples of suitable platinum compounds include platinum black, platinum halides (such as PtCl₄, H₂PtCl₄.6H₂O, Na₂PtCl₄.4H₂O, and reaction products of H₂PtCl₄.6H₂O and cyclohexane), platinum-olefin complexes, platinum-alcohol complexes, platinum-alcoholate complexes, platinum-ether complexes, platinum-aldehyde complexes, platinum-ketone complexes, platinum-vinylsiloxane complexes (such as platinum-1,3-divinyl-1,1,3,3-tetramethyldisiloxane complex), bis-(γ-picoline)-platinum dichloride, trimethylenedipyridine-platinum dichloride, dicyclopentadiene-platinum dichloride, cyclooctadiene-platinum dichloride, cyclopentadiene-platinum dichloride, bis(alkynyl)bis(triphenylphosphine)-platinum complex, and bis(alkynyl) (cyclooctadiene)-platinum complex. Furthermore, the addition reaction catalyst may also be used in a microcapsulated form. These microcapsules comprise ultra fine particles of a thermoplastic resin or the like (such as a polyester resin or a silicone resin) containing the catalyst, and are insoluble in the organopolysiloxane. Furthermore, the addition reaction catalyst may also be used in the form of a clathrate compound, wherein the catalyst is enclosed within cyclodextrin or the like. The addition reaction catalyst is used in an effective quantity (that is, so-called catalytic quantity). A typical quantity, expressed as a metal equivalent value, is within a range from 1 to 1000 ppm relative to the component (a), and quantities from 2 to 500 ppm are preferred.

A cured product produced from a composition of the present invention preferably displays resin-like hardness following the cross linking initiated by the addition reaction. A preferred hardness level, expressed as a Shore D hardness in accordance with the JIS standard, is within a range from 30 to 90, and even more preferably from 40 to 90. A cured product with a hardness level within this range can be obtained by ensuring that the degree of branching of the component (a), as expressed by the formula (2D+3T+4Q)/(D+T+Q), falls within the specified range.

Examples of LEDs that can be used with the present invention include conventional GaP, GaAs, and GaN based red, green, and yellow LEDs, as well as the more recently developed high brightness, short wavelength LEDs. Although a composition of the present invention can be used for encapsulating conventional LEDs, it is most effective when used for encapsulating the more recently developed high brightness, short wavelength LEDs, including high brightness blue LEDs, white LEDs and LEDs in the blue to near ultraviolet spectrum, namely LEDs in which the peak wavelength of the emitted light falls within a range from 490 to 350 nm. The encapsulating material used with these types of LEDs not only requires good light resistance relative to light of blue through ultraviolet wavelengths, but also requires superior light resistance and heat resistance, as it is exposed to a higher brightness, higher energy light emitted from the LED. An encapsulating composition of the present invention provides superior light resistance and heat resistance to that offered by conventional epoxy based encapsulants, meaning the lifespan of the LED can be improved significantly. Specific examples of these high brightness blue LEDs, white LEDs, and LEDs in the blue to near ultraviolet spectrum include AlGaInN yellow LEDs, InGaN blue and green LEDs, and white light emitting elements that employ a combination of InGaN and a fluorescent material.

Specific examples of encapsulated LEDs include lamp-type LEDs, large scale package LEDs, and surface mounted LEDs. These different types of LED are described, for example, in “Flat Panel Display Dictionary,” published by Kogyo Chosakai Publishing Co., Ltd., publication date 25 Dec. 2001, pp. 897 to 906.

An LED encapsulating resin must be transparent in order to allow light to pass through the resin, should have a high refractive index so that the light glows and appears bright, and must undergo minimal deformation in order to protect the high-precision light emitting element (the bonding wire in particular is easily broken by impact or deformation), that is, must display a reasonable level of hardness. In order to ensure resistance to dropping or other impacts, the resin must also be resistant to cracking. In addition, as described above, the resin must display good light resistance, and because the light emitting portion becomes very hot, must also display good heat resistance (both short-term and long-term heat resistance). The properties of light resistance and heat resistance not only ensure the maintenance of the mechanical strength of the resin, but are also important in preventing deterioration in the light transmittance of the encapsulant, and ensuring that problems such as coloring do not arise. A composition of the present invention is able to satisfy all of the above requirements, and is extremely effective as an LED encapsulating composition.

There are no particular restrictions on the encapsulating method employed, and for example a silicone composition can be fed into a concave resin mold, the light emitting element then immersed in the composition, and the temperature then raised to cure the silicone composition. A further feature of the present invention is that unlike conventional epoxy based encapsulants, the present invention can also be used with metal molds as well as resin molds.

Furthermore, other additives may also be added to a composition of the present invention, provided their addition does not impair the effects provided by the invention. Examples of possible additives include addition reaction control agents for imparting improved curability and pot life, reactive or non-reactive straight chain or cyclic low molecular weight polyorganosiloxanes or the like for regulating the hardness and viscosity of the composition, and fluorescent agents such as YAG to enable the emission of white light. Where necessary, other additives including inorganic fillers or pigments such as fine particulate silica and titanium dioxide and the like, organic fillers, metal fillers, fire retardants, heat resistant agents, and anti-oxidants may also be added.

Compositions of the present invention can be used in a wide variety of fields. Examples include the obvious fields of visible light LEDs and invisible light LEDs, as well as fields such as simple and divided light receiving elements, light emitting and receiving composite elements, optical pickups, and organic EL light emitting elements.

### EXAMPLES

As follows is a description of specifics of the present invention based on a series of examples, although the present invention is in no way restricted to the examples presented below. The evaluations were conducted in the manner described below.

Transmittance

Using a UV-visible spectral analyzer UV1240 manufactured by Shimadzu Corporation, the transmittance was measured for the range from 400 nm to 750 nm, and the lowest value was recorded as the transmittance.

Refractive Index

The refractive index was measured in accordance with JIS K7105.

Light Resistance

Using a UVCON ultraviolet/condensation weathering device manufactured by Toyo Seiki Kogyo Co., Ltd., samples were exposed to a lamp of wavelength 340 nm for 200 hours, and any color variation was determined by visual inspection and the color was recorded.

Heat Resistance

Samples were placed in an oven at 200° C. for 24 hours, and any color variation was recorded.

Hardness

Hardness was measured using a Barcol hardness tester, in accordance with JIS K7060, and the result was expressed as a Shore D value.

Cracking Resistance

Five test pieces were dropped from a height of 50 cm, and if one or more of the test pieces cracked the composition was evaluated as “poor”, if no test pieces cracked the composition was evaluated as “good”, and if none of the test pieces displayed any form of cracking or fine crazing, then the composition was evaluated as “excellent”.

Shrinkage During Molding

The diameter of a test piece was measured and compared with the internal diameter of the mold, enabling the rate of mold shrinkage to be determined.

Syntheses of the polyorganosiloxanes were performed in the manner described below. In the average composition formulas described in the synthetic examples, Me represents a methyl group, Ph represents a phenyl group, and Vi represents a vinyl group.

Synthesis of a-11

A mixture of 54.0 g (55 mol %) of phenyltrichlorosilane, 24.7 g (15 mol %) of dimethyldichlorosilane, and 148.4 g (30 mol %) of methylvinyldichlorosilane was added dropwise over a 1 hour period, with constant stirring, to a flask containing a mixed solvent of 500 g of water and 200 g of toluene that had been preheated to a temperature of 80° C. Following completion of the dropwise addition, the reaction mixture was refluxed for 2 hours, yielding a toluene solution of a cohydrolysis-condensation product. This solution was allowed to stand and cool to room temperature, and the separated water layer was then removed. A water washing operation involving adding further water, stirring, allowing the mixture to settle, and then removing the water layer was repeated until the toluene layer became neutral, and the reaction was then stopped. The thus obtained toluene solution of a polyorganosiloxane was filtered to remove impurities, and the toluene was then removed by reduced pressure distillation, yielding a liquid polyorganosiloxane with the formula shown below, which corresponds to a component (a-1). The number shown to the right of each unit represents the molar ratio.
(Me₂SiO_{2/2})_{0.15}.(MeViSiO_{2/2}) _{0.30}.(PhSiO_{3/2})_{0.55}
Synthesis of a-12

Using the same procedure as that described for a-11, a cohydrolysis-condensation of a mixture comprising 55 mol % of phenyltrichlorosilane, 15 mol % of phenylmethyldichlorosilane, and 30 mol % of methylvinyldichlorosilane yielded a liquid polyorganosiloxane with the formula shown below, which also corresponds to a component (a-1).
(PhMeSiO_{2/2})_{0.15}.(MeViSiO_{2/2})_{0.30}.(PhSiO_{3/2})_{0.55}
Synthesis of a-13

Using the same procedure as that described for a-11, a cohydrolysis-condensation of a mixture comprising 45 mol % of phenyltrichlorosilane, 15 mol % of dimethyldichlorosilane, 15 mol % of methylvinyldichlorosilane, and 25 mol % of trimethylchlorosilane yielded a liquid polyorganosiloxane with the formula shown below, which also corresponds to a component (a-1).
(Me₃SiO_{1/2})_{0.25}.(Me₂SiO_{2/2})_{0.15}.(MeViSiO_{2/2})_{0.15}.(PhSiO_{3/2})_{0.45}
Synthesis of a-21

53.6 g (22 mol %) of 1,1,3,3-tetramethyldisiloxane, 195.2 g (45 mol %) of diphenyldimethoxysilane, and 144.0 g (33 mol %) of 1,3,5,7-tetramethylcyclotetrasiloxane were combined in a flask, and with the temperature at 10° C., 17.8 g of concentrated sulfuric acid and 15.4 g of pure water were added sequentially to the reaction mixture, which was then stirred for 12 hours to effect hydrolysis and an equilibration reaction. Subsequently, 5.9 g of water and 195.8 g of toluene were added into the reaction liquid and stirred to stop the reaction, and a water washing operation involving adding further water, stirring, allowing the mixture to settle, and then removing the water layer was repeated until the toluene layer became neutral. The toluene was removed by reduced pressure distillation to yield an organohydrogenpolysiloxane, which was then filtered to remove impurities, yielding a liquid polyorganosiloxane with the formula shown below, which corresponds to a component (a-2).
(Me₂HSiO_{1/2})_{0.2}.(Ph₂SiO_{2/2})_{0.2}.(MeHSiO_{2/2})_{0.6}
Synthesis of a-22

Using the same procedure as that described for a-21, a hydrolysis and equilibration reaction of a mixture comprising 30 mol % of 1,1,1,3,3,3-hexamethyldisiloxane, 40 mol % of diphenyldimethoxysilane, and 30 mol % of 1,3,5,7-tetramethylcyclotetrasiloxane yielded a liquid polyorganosiloxane with the formula shown below, which also corresponds to a component (a-2).
(Me₃SiO_{1/2})_{0.27}.(Ph₂SiO_{2/2})_{0.18}.(MeHSiO_{2/2})_{0.55}
Synthesis of a-31

Using the same procedure as that described for a-11, a cohydrolysis-condensation of a mixture comprising 45 mol % of phenyltrichlorosilane, 15 mol % of methyldichlorosilane, 15 mol % of methylvinyldichlorosilane, and 25 mol % of trimethylchlorosilane yielded a liquid polyorganosiloxane with the formula shown below, which corresponds to a component (a-3).
(Me₃SiO_{1/2})_{0.25}.(MeHSiO_{2/2})_{0.15}.(MeViSiO_{2/2})_{0.15}.(PhSiO_{3/2})_{0.45}

### Examples 1 to 5

For each example, the respective quantities of the components shown in Table 1 were combined in a circular cylindrical aluminum container of diameter 5 cm and then stirred thoroughly. A platinum catalyst was then added in a quantity equivalent to 200 ppm of the platinum metal, and the mixture was once again subjected to thorough stirring. The container was then placed in an oven at 200° C. and heated for 5 hours. Following cooling to room temperature the test sample was removed from the container and subjected to a variety of measurements and evaluations. When the refractive index was measured for the test samples from the examples 1 and 4, the results were 1.50 for the example 1 and 1.51 for the example 4, which represent excellent refractive index values comparable with those obtained for epoxy resins. The results of other evaluations are shown in Table 1.

### Comparative Example 1

To a mixture of 100 parts of an epoxy resin YX-8000 manufactured by Japan Epoxy Resin Co., Ltd., and 83 parts of an acid anhydride curing agent MH-700, was added 1 part of a curing accelerant SA-102, and the mixture was then cured by heating at 100° C. for 4 hours, and then at 150° C. for a further 6 hours. The remaining conditions were identical to those employed in the example 1.

TABLE 1

| | | | | | | Comparative |
|---|---|---|---|---|---|---|
| | | Examples | | | | Example |
| | | 1 | 2 | 3 | 4 | 1 |
| Composition | a-11 | 80 | 0 | 75 | 0 | |
| wt % | a-12 | 0 | 75 | 0 | 0 | |
| | a-13 | 0 | 0 | 0 | 10 | |
| | a-21 | 20 | 0 | 0 | 0 | |
| | a-22 | 0 | 25 | 25 | 0 | |
| | a-31 | 0 | 0 | 0 | 90 | |
| Characteristics | Transmittance | 91% | 90% | 89% | 95% | 80% |
| | Light resistance | no change | no change | no change | no change | light yellow |
| | Heat resistance | no change | no change | no change | no change | yellow |
| | Hardness | 70 | 69 | 68 | 71 | 82 |
| | Cracking resistance | Good | Good | Good | Excellent | Good |
| | Shrinkage during | 0.3 | 0.3 | 0.3 | 0.2 | 2 |
| | molding | | | | | |

An LED encapsulating composition according to the present invention displays a high transmittance and high refractive index, as well as excellent light resistance and heat resistance, is hard and resistant to cracking, and displays little shrinkage during molding, making it ideal as a transparent encapsulating material for LEDs. It is particularly effective as a encapsulating composition for high brightness LEDs and white light emitting LEDs.

What is claimed:

1. An LED encapsulating composition which cures to a resinous material, comprising:
a) a polyorganosiloxane component, which comprises at least one polyorganosiloxane and has an average compositional formula as a mixture, of (R¹R²R³SiO_{1/2})_{M}.(R⁴R⁵SiO_{2/2})_{D}.(R⁶SiO_{3/2})_{T}.(SiO_{4/2})_{Q}, wherein, R¹ to R⁶ are identical or different radicals selected from the group consisting of organic groups, hydroxyl groups, and hydrogen, at least one of R¹ to R⁶ is either a hydrocarbon group with a multiple bond, or a hydrogen atom, and at least one of R¹ to R⁶ is an identical or different aromatic group, M, D, T, and Q each represent a number within a range from 0 to less than 1, M+D+T+Q=1, and Q+T>0); and
b) an effective amount of an addition catalyst to cure said composition.

2. The LED encapsulating composition of claim 1, wherein 3.0>(2D+3T+4Q)/(D+T+Q)>2.0 is satisfied.

3. The LED encapsulating composition of claim 1, wherein silicon atoms bonded directly to hydrogen atoms in the polyorganosiloxane are borne on no more than 40 mol % of the total number of silicon atoms.

4. The LED encapsulating composition of claim 1, wherein the component (a) comprises:
a-1) at least one polyorganosiloxane, with an average compositional formula of
(R¹R²R³SiO_{1/2})_{M1}.(R⁴R⁵SiO_{2/2})_{D1}.(R⁶SiO_{3/2})_{T1}.(SiO_{4/2})_{Q1},
which contains no hydrogen atoms bonded directly to silicon atoms, in which at least one of R¹ to R⁶ represents a hydrocarbon group with a multiple bond, wherein, M1, D1, T1 and Q1 each represent a number within a range from 0 to less than 1, M1+D1+T1+Q1=1, and Q1+T1>0; and
a-2) at least one polyorganosiloxane, with an average compositional formula of
(R¹R²R³SiO_{1/2})_{M2}.(R⁴R⁵SiO_{2/2})_{D2}.(R⁶SiO_{3/2})_{T2}.(SiO_{4/2})_{Q2},
which contains no hydrocarbon groups with a multiple bond, in which at least one of R¹ to R⁶ represents a hydrogen atom bonded directly to a silicon atom wherein, M2, D2, T2 and Q2 each represent a number within a range from 0 to less than 1, and M2+D2+T2+Q2=1).

5. The LED encapsulating composition of claim 1, wherein component (a) comprises:
a-1) at least one polyorganosiloxane, with an average compositional formula of
(R¹R²R³SiO_{1/2})_{M1}.(R⁴R⁵SiO_{2/2})_{D1}.(R⁶SiO_{3/2})_{T1}.(SiO_{4/2})_{Q1},
which contains no hydrogen atoms bonded directly to silicon atoms, in which at least one of R¹ to R⁶ represents a hydrocarbon group with a multiple bond, wherein, M1, D1, T1 and Q1 each represent a number within a range from 0 to less than 1, M1+D1+T1+Q1=1, and Q1+T1>0; and
a-3) at least one polyorganosiloxane, with an average composition formula of
(R¹R²R³SiO_{1/2})_{M3}.(R⁴R⁵SiO_{2/2})_{D3}.(R⁶SiO_{3/2})_{T3}.(SiO_{4/2})_{Q3},
in which at least one of R¹ to R⁶ represents a hydrocarbon group with a multiple bond, and at least one of R¹ to R⁶ represents a hydrogen atom bonded directly to a silicon atom, wherein, M3, D3, T3 and Q3 each represent a number within a range from 0 to less than 1, and M3+D3+T3+Q3=1.

6. The LED encapsulating composition of claim 4, wherein the hydrocarbon group with a multiple bond is a vinyl group.

7. The LED encapsulating composition of claim 5, wherein the hydrocarbon group with a multiple bond is a vinyl group.

8. An LED encapsulated with the composition of claim 1.

9. An LED encapsulated with the composition of claim 2.

10. An LED encapsulated with the composition of claim 3.

11. An LED encapsulated with the composition of claim 4.

12. An LED encapsulated with the composition of claim 5.

13. An LED encapsulated with the composition of claim 6.

14. An LED encapsulated with the composition of claim 7.

15. In a process for the encapsulation of an LED device with a transparent polymer composition, the improvement comprising employing as at least a portion of an LED encapsulant, the LED encapsulating composition of claim 1.

16. In a process for the encapsulation of an LED device with a transparent polymer composition, the improvement comprising employing as at least a portion of an LED encapsulant, the LED encapsulating composition of claim 2.

17. In a process for the encapsulation of an LED device with a transparent polymer composition, the improvement comprising employing as at least a portion of an LED encapsulant, the LED encapsulating composition of claim 3.

18. In a process for the encapsulation of an LED device with a transparent polymer composition, the improvement comprising employing as at least a portion of an LED encapsulant, the LED encapsulating composition of claim 4.

19. In a process for the encapsulation of an LED device with a transparent polymer composition, the improvement comprising employing as at least a portion of an LED encapsulant, the LED encapsulating composition of claim 5.

20. In a process for the encapsulation of an LED device with a transparent polymer composition, the improvement comprising employing as at least a portion of an LED encapsulant, the LED encapsulating composition of claim 6.
